(19) United States
(12) Patent Application Publication
(10) Pub. No.: US 2008/0047816 A1
(43) Pub. Date: Feb. 28, 2008

(54) MEMS SWITCH

(75) Inventors: Takashi Kawakubo, Yokohama-shi (JP); Toshihiko Nagano, Kawasaki-shi (JP); Michihiko Nishigaki, Kawasaki-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/779,367

(22) Filed: Jul. 18, 2007

(30) Foreign Application Priority Data
Aug. 25, 2006 (JP) 2006-228748

(51) Int. Cl. H01H 1/04; B81B 3/00

(52) U.S. Cl. 200/512

(57) ABSTRACT

A Micro-Electro-Mechanical System (MEMS) switch includes: a substrate; a fixed electrode provided on the substrate; and a beam fixed to the substrate and including a movable electrode disposed to face the fixed electrode. The beam is capable of being bent and displaced in a direction of the substrate to allow the movable electrode to directly contact with the fixed electrode. At least one of the fixed electrode and the movable electrode contains Au, and the other contains at least one metal selected from a group consisting of Ir, Rh, Os, Ru, Re and Te as a main component.

### CROSS-REFERENCE TO RELATED APPLICATIONS

This application is based upon and claims the benefit of priority from Japanese Patent Application No. 2006-228748, filed on Aug. 25, 2006, the entire contents of which are incorporated herein by reference.

### BACKGROUND

1. Field

The present invention relates to an MEMS switch that can be applied as a switch for a high frequency circuit.

2. Description of the Related Art

In recent years, attention has been given to a technique for manufacturing switches by using actuators manufactured by the Micro-Electro-Mechanical System (MEMS). In particular, the switches have a lower loss and a higher insulating characteristic in OFF state as compared with a semiconductor switch that is generally used for a high frequency including a cellular phone and a car phone.

The switch for a high frequency is roughly classified into two types including a direct contact type MEMS switch (hereinafter referred to as a “DC type MEMS switch”) and a capacitive type. The DC type MEMES switch allows a movable electrode to directly come in contact with a fixed electrode. The capacitive type can be used with only a high frequency of 10 GHz or more and allows a fixed electrode to connect with a movable electrode via a very thin dielectric film interposed between the movable electrode and the fixed electrode. At present, a cellular phone for consumers is mainly used in a band of approximately 500 MHz to 5 GHz. Therefore, a usefulness of the DC type MEMS switch is high.

Au (gold) is generally used for the movable electrode and the fixed electrode in the MEMS switch. Au has advantages as follows: high conductive property; hardly oxidized as compared with other metals; and easily deformed that enables increasing a contact area. Therefore, it is possible to maintain a high conduction (a state in which a contact resistance is low) in a fine switch such as the MEMS switch. However, Au has a higher adhesion coefficient than the other metals. For this reason, the movable electrode and the fixed electrode may adhere to each other.

JP-A 2001-266727 (KOKAI) discloses a technique capable of reducing an adhesive capacity so as not to be concerned in an operating characteristic by using Ru (ruthenium), Rh (rhodium) or AuCo (gold cobalt) for a material of a contact electrode.

In the DC type MEMS switch, however, more micro fusion bonding and breakage are actually repeated on a contact point of the movable electrode and the fixed electrode. Therefore, when ON-OFF of the switch is repeated, the contact point gradually generates a surface roughness, which may finally generate a contact failure and reduce a lifetime of the MEMS switch.

### SUMMARY

According to a first aspect of the invention, there is provided a Micro-Electro-Mechanical System (MEMS) switch including: a substrate; a fixed electrode provided on the substrate; and a beam fixed to the substrate and including a movable electrode disposed to face the fixed electrode, and the beam capable of being bent and displaced in a direction of the substrate to allow the movable electrode to directly contact with the fixed electrode, wherein at least one of the fixed electrode and the movable electrode contains Au, and the other contains at least one metal selected from a group consisting of Ir, Rh, Os, Ru, Re and Te as a main component.

According to a second aspect of the invention, there is provided a Micro-Electro-Mechanical System (MEMS) switch including: a substrate; a fixed electrode provided on the substrate; and a beam fixed to the substrate and including a movable electrode disposed to face the fixed electrode, and the beam capable of being bent and displaced in a direction of the substrate to allow the movable electrode to directly contact with the fixed electrode, wherein at least one of the fixed electrode and the movable electrode contains Au, and the other contains at least one metal selected from a group consisting of TiN, ZrN, HfN and VN as a main component.

### BRIEF DESCRIPTION OF THE DRAWINGS

FIG. 1 is a plan view showing an MEMS switch according to an embodiment;

FIG. 2 is a sectional view taken along a II-II line shown in FIG. 1;

FIG. 3 is a sectional view showing a process for explaining a method for manufacturing the MEMS switch according to the embodiment;

FIG. 4 is a sectional view showing a process in the method;

FIG. 5 is a sectional view showing a process in the method;

FIG. 6 is a sectional view showing a process in the method;

FIG. 7 is a sectional view showing a process in the method; and

FIG. 8 is a plan view showing another example of the MEMS switch according to the embodiment.

### DETAILED DESCRIPTION

The inventors made various investigations for maintaining a low contact resistance in the DC type MEMS switch. As a result, it was found that: a contact portion is to be sufficiently deformed to increase a contact area of a movable electrode and a fixed electrode; and one of the movable electrode and the fixed electrode optimally uses Au in consideration of a high conductivity and a difficult oxidation. Moreover, in order to prolong a lifetime, it was found that a material hard to be fusion bonded to Au was to be used for an electrode making a pair with Au.

The materials hard to be fusion bonded represents, in material chemical terms, materials hard to mutually mixed, that is, both metals do not form solid solutions with each other in an equilibrium state diagram. Moreover, the materials hard to be fusion bonded represents, in thermodynamic terms, a heat of mixture of both of the metals is positive. The inventors found that the material hard to be fusion bonded to Au is Ir (iridium), Rh (rhodium), Os (osmium), Ru (ruthenium), Re (rhenium) and Tc (technetium).

Furthermore, the inventors found that a metal nitride to be a metal material having conductivity is effective for the material hard to be fusion bonded to Au. In particular, TiN (titanium nitride), ZrN (zirconium nitride), HfN (hafnium nitride) and VN (vanadium nitride) have low contact resistances and are hard to be oxidized at an ordinary temperature and to be fusion bonded to Au. Therefore, it was found that these materials were suitable for a material of the electrode making a pair with Au.

An embodiment of the invention will be described below in detail with reference to the drawings. In the following description of the drawings, the same portions have the same reference numerals and repetitive description will be omitted. Moreover, the drawings are typical, and a relationship between a thickness and a planar dimension and a ratio of thicknesses of respective layers are different from actual ones. Furthermore, the mutual drawings include portions having a relationship and a ratio of the mutual dimensions which are different.

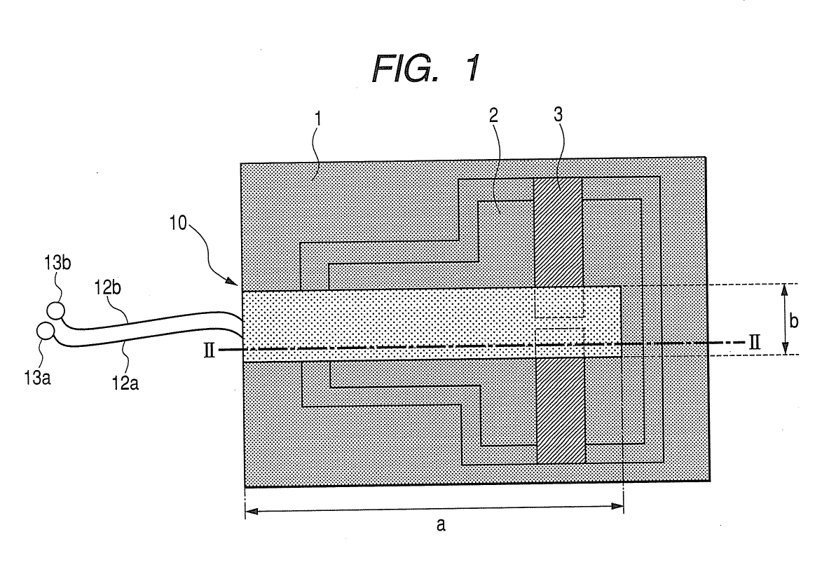

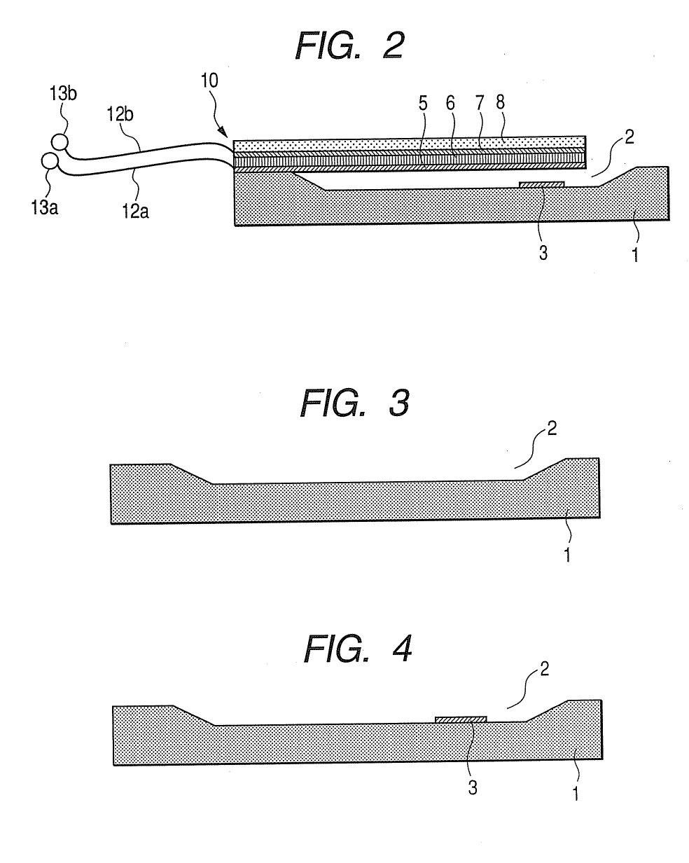

The MEMS switch according to the embodiment is used for a series type MEMS switch having two fixed electrodes. As shown in FIGS. 1 and 2, the MEMS switch includes: a substrate 1; a fixed electrode 3 disposed in a trench 2 provided on the substrate 1; and a beam 10 provided on the substrate 1 and having a part disposed to face the fixed electrode 3.

The beam 10 includes a lower electrode 5, a piezoelectric film 6 provided on the lower electrode 5, an upper electrode 7 provided on the piezoelectric film 6 and a support film 8 provided on the upper electrode 7. The lower electrode 5 has one end disposed on the substrate and at a region except the trench 2 and the other end disposed to face the fixed electrode 3 that is disposed on the substrate 1.

Wirings 12a and 12b are connected to the lower electrode 5 and the upper electrode 7, respectively. Terminals 13a and 13b are provided on the wirings 12a and 12b, respectively. The terminals 13a and 13b have the function of voltage applying means for applying a voltage to the lower electrode 5 and the upper electrode 7 to drive the piezoelectric film 6 to expand and contract, respectively.

When a voltage is applied from the terminal 13a to the lower electrode 5 and from the terminal 13b to the upper electrode 7 respectively, the piezoelectric film 6 is distorted, and expanded and contracted by a reverse piezoelectric effect. For example, when an electric potential of the terminal 13b is set to be higher than that of the terminal 13a, the piezoelectric film 6 is contracted by the reverse piezoelectric effect so that the beam 10 is bent and displaced toward the substrate 1 side. To the contrary, when the electric potential of the terminal 13b is set to be lower than that of the terminal 13a, the piezoelectric film 6 is expanded by the reverse piezoelectric effect and the beam 10 is bent and displaced in an opposite direction to the substrate 1 side.

The lower electrode 5 provided on the beam 10 acts as the movable electrode and is vertically displaced in the direction of the substrate 1 corresponding to the bending and displacement of the beam 10. The lower electrode 5 is allowed to directly come in contact with the fixed electrode 3 by the displacement so that the MEMS switch can be ON/OFF controlled.

It is preferable that at least one of the lower electrode 5 (the movable electrode) and the fixed electrode 3 contains Au. When both the lower electrode 5 and the fixed electrode 3 are made of Au, a contact resistance can be maintained to be low but a micro fusion bonding is generated so that the lifetime of the MEMS switch is shortened, which is not preferable. When Au is used for neither the lower electrode 5 nor the fixed electrode 3, moreover, the contact resistance is raised, which is not preferable.

It is preferable that one electrode making a pair with the other electrode containing Au contains, as a main component, at least one metal selected from Ir, Rh, Os, Ru, Re and Tc. The “main component” in this embodiment indicates that weight percentage of a component contained in the electrode is equal to or higher than 50% by weight. Examples of the material to be used for the electrode include Pt (platinum) and Pd (palladium). They are easily fusion bonded to Au and the lifetime of the MEMS switch is shortened, which is not preferable.

Moreover, it is preferable that the electrode making a pair with Au contains, as a main component, at least one metal selected from nitrides of metal materials (TiN, ZrN, HfN, VN). In addition, the nitrides of the metal materials include NbN (niobium nitride) and TaN (tantalum nitride) Although they are hard to fusion bonded to Au, the contact resistance is raised, which is not preferable.

An insulating glass substrate or a semiconductor substrate of silicon (Si) is suitably used for the substrate 1.

For the piezoelectric film 6, for example, there is suitably used a wurtzite type crystal such as aluminum nitride (AlN) or zinc oxide (ZnO) or a perovskite based ferroelectric substance such as lead titanate zirconate (PZT) or barium titanate (BTO).

If the upper electrode 7 contains a material having conductivity, it is not particularly limited. In the embodiment, a case where Au is used will be described.

The support film 8 includes a polysilicon film, for example.

Next, a method for manufacturing the MEMS switch shown in FIGS. 1 and 2 will be described.

First of all, the trench 2 having a taper provided on an end thereof is formed on the insulating glass substrate 1 by lithography and RIE etching, for example (FIG. 3).

Next, the fixed electrode 3 is formed on a bottom portion of the trench 2 by using a lift off process (FIG. 4).

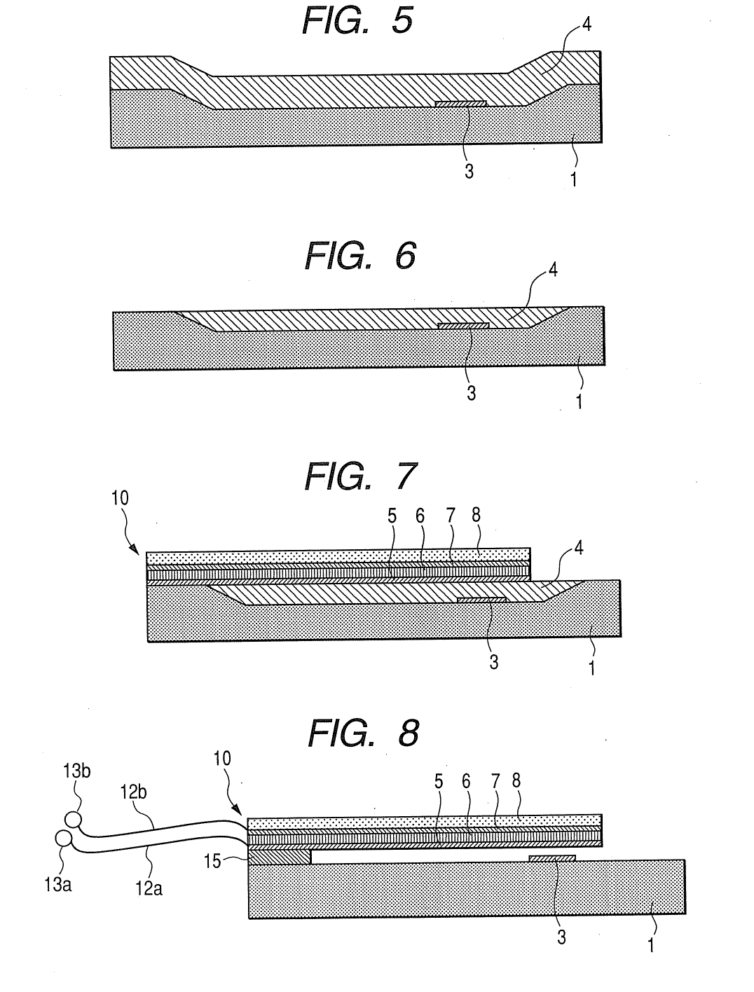

Next, a sacrificial layer 4 is formed to fill in the trench 2 (FIG. 5). For the sacrificial layer 4, it is possible to use an inorganic material, a metallic material and an organic material so that selective etching can be performed for other film materials. In the embodiment, polycrystalline silicon is suitably used.

Then, the sacrificial layer 4 is flattened until the surface of the glass substrate 1 is exposed by a CMP technique (FIG. 6).

Thereafter, the lower electrode 5, the piezoelectric film 6, the upper electrode 7 and the support film 8 are provided on the glass substrate 1 and the sacrificial layer 4 in this order by sputtering and CVD methods, and they are patterned by lithography and etching to form the beam 10 (FIG. 7).

Finally, the sacrificial layer 4 formed in the trench 2 is removed by selective etching using XeF₂ and the wirings 12a and 12b and the terminals 13a and 13b are connected to the lower electrode 5 and the upper electrode 7 so that the MEMS switch shown in FIGS. 1 and 2 is manufactured.

The invention is not limited to the MEMS switch shown in FIGS. 1 and 2. For example, as shown in FIG. 8, instead of providing the trench 2, an MEMS switch may include the fixed electrode 3 provided on the substrate 1, and the beam 10 is fixed on an anchor 15 and above the substrate 1, which can obtain the similar advantages in the MEMS switch shown in FIGS. 1 and 2.

Next, description will be given to specific examples according to the invention.

### EXAMPLES 1 to 6

The MEMS switch shown in FIGS. 1 and 2 was fabricated by the manufacturing method illustrated in FIGS. 3 to 7. In this case, the metallic materials to be used for the fixed electrode 3 and the lower electrode 5 were assigned on conditions shown in Table 1 (Examples 1 to 6) respectively to fabricate the MEMS switch. Other conditions are as follows:

thickness of the fixed electrode 3: 200 nm;

thickness of the lower electrode 5: 200 nm;

the piezoelectric film 6: c-axis oriented AlN (thickness of 500 nm);

the upper electrode 7: Au (thickness of 200 nm);

the support film 8: polysilicon layer (thickness of 600 nm);

length of major axis of the beam 10 (“a” in FIG. 1): 200 μm; and

length of minor axis of the beam 10 (“b” in FIG. 1): 100 μm.

There were respectively evaluated lifetimes (number of ON-OFF operations of the MEMS switch) obtained until an initial contact resistance value and an initial resistance value of the MEMS switch created on the conditions were doubled.

### COMPARATIVE EXAMPLES 1 to 6

The MEMS switch shown in FIGS. 1 and 2 was fabricated by the manufacturing method illustrated in FIGS. 3 to 7. In this case, the metallic materials used for the fixed electrode 3 and the lower electrode 5 were assigned on conditions shown in Table 1 (Comparative Examples 1 to 6) respectively to fabricate the MEMS switch. Other conditions were set to be the same as those in the Examples 1 to 6.

There were respectively evaluated lifetimes obtained until an initial contact resistance value and an initial resistance value of the MEMS switch created on the conditions were doubled.

Table 1 shows evaluation results related to the Examples 1 to 6 and the Comparative Examples 1 to 6.

TABLE 1

| | | | Initial | |
|---|---|---|---|---|
| | | | contact | |
| | Fixed | Lower | resistance | |
| | electrode | electrode | value Ω | Lifetime |
| Example 1 | Au | Ir | 0.8 | >10⁸ |
| Example 2 | Au | Rh | 0.7 | >10⁸ |
| Example 3 | Au | Os | 1.5 | >10⁸ |
| Example 4 | Au | Ru | 1.2 | >10⁸ |
| Example 5 | Au | Re | 2.8 | >10⁸ |
| Example 6 | Au | Tc | 1.8 | >10⁸ |
| Comparative | Au | Au | 0.4 | 10⁴ |
| Example 1 | | | | |
| Comparative | Au | Pt | 1.6 | 10⁶ |
| Example 2 | | | | |
| Comparative | Au | Pd | 1.5 | 10⁵ |
| Example 3 | | | | |
| Comparative | Ir | Ir | 25.3 | >10⁸ |
| Example 4 | | | | |
| Comparative | Ir | Pt | 12.8 | >10⁸ |
| Example 5 | | | | |
| Comparative | Ir | Pd | 10.9 | >10⁸ |
| Example 6 | | | | |

As is apparent from Table 1, according to the Examples 1 to 6, that is, in the MEMS switches in which Au is used for the fixed electrode 3 and Ir, Rh, Os, Ru, Re and Tc are used for the lower electrode 5, it was confirmed that the initial contact resistances are very low, that is, 0.7 to 2.8Ω and all of the lifetimes are very long, that is, 10⁸ times or more. The reason is as follows. It can be supposed that the advantages are obtained because Au is deformed to maintain a large contact area, resulting in a reduction in a contact resistance in an initial contact of electrodes, and furthermore, the electrodes do not bring a solid solution state as is apparent from an equilibrium state diagram shown in Table 2 and heats of mixture of the metals are high, that is, Au—Ir (53 KJ/mol), Au—Rh (31 KJ/mol), Au—Os (77 KJ/mol), Au—Ru (65 KJ/mol), Au—Re (83 KJ/mol) and Au—Tc (59 KJ/mol).

On the other hand, according to the Comparative Examples 1 to 3, that is, in the MEMS switches in which Au is used as the fixed electrode 3 and Au, Pt and Pd are used as the lower electrode 5, it was confirmed that the initial contact resistances are very low, that is, 0.4 to 1.6Ω but the lifetimes are reduced by two digits or more as compared with those in the Examples. The reason is as follows. It can be supposed that a micro fusion bonding is easily generated because combinations of Au—Au, Au—Pt and Au—Pd easily bring the solid solution state in the equilibrium state diagram shown in Table 2 and their heats of mixture are also low, that is, Au—Au (0 KJ/mol), Au—Pt (18 KJ/mol) and Au—Pd (0 KJ/mol).

TABLE 2

| First | Second | |
|---|---|---|
| element | element | State diagram |
| Au | Pt | 20% of Pt solid-solved in Au and |
| | | 4% of Au solid-solved in Pt |
| | | at 600° C. |
| | Pd | Full ratio solid-solved |
| | Ir | Not solved, no compound |
| | Rh | Not solved, no compound |
| | Os | Not solved, no compound |
| | Ru | Not solved, no compound |
| | Re | Not solved, no compound |
| | Tc | Not solved, no compound |

According to the Comparative Examples 4 to 6, in the MEMS switches using Ir as the fixed electrode 3 and using Ir, Pt and Pd as the lower electrode 5, it was confirmed that all of the lifetimes are very long, that is, 10⁸ times or more and the initial contact resistances are high. The reason is as follows. It can be supposed that a large contact area cannot be maintained in the contact because all of Ir, Pt and Pd are hard and hardly deformed.

### EXAMPLE 7

The MEMS switch shown in FIGS. 1 and 2 was fabricated by the manufacturing method illustrated in FIGS. 3 to 7. In this example, there were investigated in case where Au was used for the fixed electrode 3; and for the lower electrode 5, an alloy of two metals selected from Ir, Rh, Os, Ru, Re and Tc which are excellent in the Examples 1 to 6 (a binary alloy: Ir—Rh, Ir—Os, Ir—Ru, Ir—Re, Ir—Tc, Rh—Os, Rh—Ru, Rh—Re, Rh—Tc, Os—Ru, Os—Re, Os—Tc, Re—Tc) and an alloy of three selected metals (a ternary alloy: Ir—Rh—Os, Ir—Rh—Ru, Ir—Rh—Re, Ir—Rh—Tc, Ir—Os—Ru, Ir—Os—Re, Ir—Os—Tc, Ir—Ru—Re, Ir—Ru—Tc, Ir—Re—Tc, Rh—Os—Ru, Rh—Os—Re, Rh—Os—Tc, Rh—Ru—Re, Rh—Ru—Tc, Rh—Re—Tc, Os—Ru—Re, Os—Ru—Tc, Os—Re—Tc, Ru—Re—Tc) were used. Other conditions were set to be the same as those in the Examples 1 to 6.

As a result, in the same manner as the results in the Examples 1 to 6, it was confirmed that the initial contact resistances are very low (1.3 to 3.8Ω) and all of the lifetimes are very long, that is, 10⁸ times or more.

### EXAMPLES 8 to 10

The MEMS switch shown in FIGS. 1 and 2 was fabricated by the manufacturing method illustrated in FIGS. 3 to 7. In this case, Au was used for the fixed electrode 3 and a binary alloy containing Ir in the metals which are excellent in the Examples 1 to 6 and Au which has the poorest result in the Comparative Examples was used for the lower electrode 5. The binary alloys were fabricated with a change of a mixing ratio (a weight ratio in this embodiment) of Ir and Au into 3:1 (Example 8), 2:1 (Example 9) and 1:1 (Example 10), respectively. The binary alloys were set to be the lower electrode 5 to fabricate the MEMS switches, respectively. Other conditions were set to be the same as those in the Examples 1 to 6.

There were evaluated lifetimes obtained until initial contact resistance values and initial resistance values of the MEMS switches created on the condition were doubled, respectively.

### COMPARATIVE EXAMPLES 7 and 8

In the same manner as in the Examples 8 to 10, Au was used for the fixed electrode 3 and a binary alloy of Ir and Au was fabricated for the lower electrode 5. The binary alloys were fabricated with a change of a mixing ratio of Ir and Au into 1:2 (Comparative Example 7) and 1:3 (Comparative Example 8), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

Table 3 shows evaluation results related to the Examples 8 to 10 and the Comparative Examples 7 and 8.

TABLE 3

| | | Lower | Initial | |
|---|---|---|---|---|
| | | electrode | contact | |
| | Fixed | (mixing ratio) | resistance | |
| | electrode | Ir:Au | value Ω | Lifetime |
| Example 8 | Au | 3:1 | 1.9 | >10⁸ |
| Example 9 | Au | 2:1 | 2.0 | >10⁸ |
| Example 10 | Au | 1:1 | 2.0 | >10⁸ |
| Comparative | Au | 1:2 | 1.6 | >10⁷ |
| Example 7 | | | | |
| Comparative | Au | 1:3 | 1.3 | >10⁶ |
| Example 8 | | | | |

As is apparent from Table 3, it was confirmed that the initial contact resistances are very low and all of the lifetimes are very long, that is, 10⁸ times or more in the same manner as those in the Examples 1 to 6 when the mixing ratio of Ir and Au of the lower electrode is 3:1, 2:1 and 1:1, that is, Ir contained in the lower electrode is equal to or higher than 50% by weight. When the weight percentage of Ir contained in the lower electrode was lower than 50% (the Comparative Examples 7 and 8), the lifetimes were reduced by approximately one digit.

### EXAMPLES 11 to 13

The MEMS switch shown in FIGS. 1 and 2 was fabricated by the manufacturing method illustrated in FIGS. 3 to 7. In this case, Au was used for the fixed electrode 3 and a binary alloy containing Rh in the metals which are excellent in the Examples 1 to 6 and Au which has the poorest result in the Comparative Examples was used for the lower electrode 5. The binary alloys were fabricated with a change of a mixing ratio of Rh and Au into 3:1 (Example 11), 2:1 (Example 12) and 1:1 (Example 13), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

### COMPARATIVE EXAMPLES 9 and 10

In the same manner as in the Examples 11 to 13, Au was used for the fixed electrode 3 and a binary alloy of Rh and Au was fabricated for the lower electrode 5. The binary alloys were fabricated with a change of a mixing ratio of Rh and Au into 1:2 (Comparative Example 9) and 1:3 (Comparative Example 10), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

Table 4 shows evaluation results related to the Examples 11 to 13 and the Comparative Examples 9 and 10.

TABLE 4

| | | Lower | Initial | |
|---|---|---|---|---|
| | | electrode | contact | |
| | Fixed | (mixing ratio) | resistance | |
| | electrode | Rh:Au | value Ω | Lifetime |
| Example 11 | Au | 3:1 | 1.8 | >10⁸ |
| Example 12 | Au | 2:1 | 1.9 | >10⁸ |
| Example 13 | Au | 1:1 | 1.8 | >10⁸ |
| Comparative | Au | 1:2 | 1.4 | >10⁷ |
| Example 9 | | | | |
| Comparative | Au | 1:3 | 1.2 | >10⁶ |
| Example 10 | | | | |

As is apparent from Table 4, it was confirmed that the initial contact resistances are very low and all of the lifetimes are very long, that is, 10⁸ times or more in the same manner as those in the Examples 1 to 6 when the mixing ratio of Rh and Au of the lower electrode is 3:1, 2:1 and 1:1, that is, Rh contained in the lower electrode is equal to or higher than 50% by weight. When the weight percentage of Rh contained in the lower electrode was lower than 50% (the Comparative Examples 9 and 10), the lifetimes were reduced by approximately one digit.

### EXAMPLES 14 and 16

The MEMS switch shown in FIGS. 1 and 2 was fabricated by the manufacturing method illustrated in FIGS. 3 to 7. In this case, Au was used for the fixed electrode 3 and a binary alloy containing Os in the metals which are excellent in the Examples 1 to 6 and Au which has the poorest result in the Comparative Examples was used for the lower electrode 5. The binary alloys were fabricated with a change of a mixing ratio of Os and Au into 3:1 (Example 14), 2:1 (Example 15) and 1:1 (Example 16), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

### COMPARATIVE EXAMPLES 11 and 12

In the same manner as in the Examples 14 to 16, Au was used for the fixed electrode 3 and a binary alloy of Os and Au was fabricated for the lower electrode 5. The binary alloys were fabricated with a change of a mixing ratio of Os and Au into 1:2 (Comparative Example 11) and 1:3 (Comparative Example 12), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

Table 5 shows evaluation results related to the Examples 14 to 16 and the Comparative Examples 11 and 12.

TABLE 5

| | | Lower | Initial | |
|---|---|---|---|---|
| | | electrode | contact | |
| | Fixed | (mixing ratio) | resistance | |
| | electrode | Os:Au | value Ω | Lifetime |
| Example 14 | Au | 3:1 | 2.3 | >10⁸ |
| Example 15 | Au | 2:1 | 2.5 | >10⁸ |
| Example 16 | Au | 1:1 | 2.3 | >10⁸ |
| Comparative | Au | 1:2 | 2.1 | >10⁷ |
| Example 11 | | | | |
| Comparative | Au | 1:3 | 1.5 | >10⁶ |
| Example 12 | | | | |

As is apparent from Table 5, it was confirmed that the initial contact resistances are very low and all of the lifetimes are very long, that is, 10⁸ times or more in the same manner as those in the Examples 1 to 6 when the mixing ratio of Os and Au of the lower electrode is 3:1, 2:1 and 1:1, that is, Os contained in the lower electrode is equal to or higher than 50% by weight. When the weight percentage of Os contained in the lower electrode was lower than 50% (the Comparative Examples 11 and 12), the lifetimes were reduced by approximately one digit.

### EXAMPLES 17 to 19

The MEMS switch shown in FIGS. 1 and 2 was fabricated by the manufacturing method illustrated in FIGS. 3 to 7. In this case, Au was used for the fixed electrode 3 and a binary alloy containing Ru in the metals which are excellent in the Examples 1 to 6 and Au which has the poorest result in the comparative examples was used for the lower electrode 5. The binary alloys were fabricated with a change of a mixing ratio of Ru and Au into 3:1 (Example 17), 2:1 (Example 18) and 1:1 (Example 19), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

### COMPARATIVE EXAMPLES 13 and 14

In the same manner as in the Examples 17 to 19, Au was used for the fixed electrode 3 and a binary alloy of Ru and Au was fabricated for the lower electrode 5. The binary alloys were fabricated with a change of a mixing ratio of Ru and Au into 1:2 (Comparative Example 13) and 1:3 (Comparative Example 14), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

Table 6 shows evaluation results related to the Examples 17 to 19 and the Comparative Examples 13 and 14.

TABLE 6

| | | Lower | Initial | |
|---|---|---|---|---|
| | | electrode | contact | |
| | Fixed | (mixing ratio) | resistance | |
| | electrode | Ru:Au | value Ω | Lifetime |
| Example 17 | Au | 3:1 | 2.0 | >10⁸ |
| Example 18 | Au | 2:1 | 2.2 | >10⁸ |
| Example 19 | Au | 1:1 | 2.1 | >10⁸ |
| Comparative | Au | 1:2 | 1.9 | >10⁶ |
| Example 13 | | | | |
| Comparative | Au | 1:3 | 1.2 | >10⁶ |
| Example 14 | | | | |

As is apparent from Table 6, it was confirmed that the initial contact resistances are very low and all of the lifetimes are very long, that is, 10⁸ times or more in the same manner as those in the Examples 1 to 6 when the mixing ratio of Ru and Au of the lower electrode is 3:1, 2:1 and 1:1, that is, Ru contained in the lower electrode is equal to or higher than 50% by weight. When the weight percentage of Ru contained in the lower electrode was lower than 50% (the Comparative Examples 13 and 14), the lifetimes were reduced by approximately one digit or more.

### EXAMPLES 20 to 22

The MEMS switch shown in FIGS. 1 and 2 was fabricated by the manufacturing method illustrated in FIGS. 3 to 7. In this case, Au was used for the fixed electrode 3 and a binary alloy containing Re in the metals which are excellent in the Examples 1 to 6 and Au which has the poorest result in the comparative examples was used for the lower electrode 5. The binary alloys were fabricated with a change of a mixing ratio of Re and Au into 3:1 (Example 20), 2:1 (Example 21) and 1:1 (Example 22), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

### COMPARATIVE EXAMPLES 15 and 16

In the same manner as in the Comparative Examples 20 to 22, Au was used for the fixed electrode 3 and a binary alloy of Re and Au was fabricated for the lower electrode 5. The binary alloys were fabricated with a change of a mixing ratio of Re and Au into 1:2 (Comparative Example 15) and 1:3 (Comparative Example 16), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

Table 7 shows evaluation results related to the Examples 20 to 22 and the Comparative Examples 15 and 16.

TABLE 7

| | | Lower | Initial | |
|---|---|---|---|---|
| | | electrode | contact | |
| | Fixed | (mixing ratio) | resistance | |
| | electrode | Re:Au | value Ω | Lifetime |
| Example 20 | Au | 3:1 | 3.3 | >10⁸ |
| Example 21 | Au | 2:1 | 3.5 | >10⁸ |
| Example 22 | Au | 1:1 | 3.3 | >10⁸ |
| Comparative | Au | 1:2 | 3.1 | >10⁷ |
| Example 15 | | | | |
| Comparative | Au | 1:3 | 2.5 | >10⁶ |
| Example 16 | | | | |

As is apparent from Table 7, it was confirmed that the initial contact resistances are very low and all of the lifetimes are very long, that is, 10⁸ times or more in the same manner as those in the Examples 1 to 6 when the mixing ratio of Re and Au of the lower electrode is 3:1, 2:1 and 1:1, that is, Re contained in the lower electrode is equal to or higher than 50% by weight. When the weight percentage of Re contained in the lower electrode was lower than 50% (the Comparative Examples 15 and 16), the lifetimes were reduced by approximately one digit or more.

### EXAMPLES 23 to 25

The MEMS switch shown in FIGS. 1 and 2 was fabricated by the manufacturing method illustrated in FIGS. 3 to 7. In this case, Au was used for the fixed electrode 3 and a binary alloy containing Tc in the metals which are excellent in the Examples 1 to 6 and Au which has the poorest result in the Comparative Examples was used for the lower electrode 5. The binary alloys were fabricated with a change of a mixing ratio of Tc and Au into 3:1 (Example 23), 2:1 (Example 24) and 1:1 (Example 25), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

### COMPARATIVE EXAMPLES 17 and 18

In the same manner as in the Examples 23 to 25, Au was used for the fixed electrode 3 and a binary alloy of Tc and Au was fabricated for the lower electrode 5. The binary alloys were fabricated with a change of a mixing ratio of Tc and Au into 1:2 (Comparative Example 17) and 1:3 (Comparative Example 18), respectively. The binary alloys were set to be the lower electrode 5 to fabricate the MEMS switches, respectively. Other conditions were set to be the same as those in the Examples 1 to 6.

There were evaluated lifetimes obtained until the initial contact resistance values and the initial resistance values of the MEMS switches created on the condition were doubled, respectively.

Table 8 shows evaluation results related to the Examples 23 to 25 and the Comparative Examples 17 and 18.

TABLE 8

| | | Lower | Initial | |
|---|---|---|---|---|
| | | electrode | contact | |
| | Fixed | (mixing ratio) | resistance | |
| | electrode | Tc:Au | value Ω | Lifetime |
| Example 23 | Au | 3:1 | 2.5 | >10⁸ |
| Example 24 | Au | 2:1 | 2.6 | >10⁸ |
| Example 25 | Au | 1:1 | 2.4 | >10⁸ |
| Comparative | Au | 1:2 | 2.3 | >10⁷ |
| Example 17 | | | | |
| Comparative | Au | 1:3 | 1.7 | >10⁶ |
| Example 18 | | | | |

As is apparent from Table 8, it was confirmed that the initial contact resistances are very low and all of the lifetimes are very long, that is, 10⁸ times or more in the same manner as those in the Examples 1 to 6 when the mixing ratio of Tc and Au of the lower electrode is 3:1, 2:1 and 1:1, that is, Tc contained in the lower electrode is equal to or higher than 50% by weight. When the weight percentage of Tc contained in the lower electrode was lower than 50% (the Comparative Examples 17 and 18), the lifetimes were reduced by approximately one digit or more.

### EXAMPLES 26 to 29

The MEMS switch shown in FIGS. 1 and 2 was fabricated by the manufacturing method illustrated in FIGS. 3 to 7. In this case, the metallic materials to be used for the fixed electrode 3 and the lower electrode 5 were assigned on conditions shown in Table 9 (Examples 26 to 29) respectively to fabricate the MEMS switch. Other conditions were set to be the same as those in the Examples 1 to 6.

There were evaluated lifetimes obtained until the initial contact resistance values and the initial resistance values of the MEMS switches created on the condition were doubled, respectively.

### COMPARATIVE EXAMPLES 19 and 20

The MEMS switch shown in FIGS. 1 and 2 was fabricated by the manufacturing method illustrated in FIGS. 3 to 7. In this case, the metallic materials to be used for the fixed electrode 3 and the lower electrode 5 were assigned on conditions shown in Table 9 (Comparative Examples 19 and 20) respectively to fabricate the MEMS switch. Other conditions were set to be the same as those in the Examples 1 to 6.

There were evaluated lifetimes obtained until the initial contact resistance values and the initial resistance values of the MEMS switches created on the condition were doubled, respectively.

Table 9 shows evaluation results related to the Examples 26 to 29 and the Comparative Examples 19 and 20.

TABLE 9

| | | | Initial | |
|---|---|---|---|---|
| | | | contact | |
| | Fixed | Lower | resistance | |
| | electrode | electrode | value Ω | Lifetime |
| Example 26 | Au | TiN | 2.9 | >10⁸ |
| Example 27 | Au | ZrN | 2.0 | >10⁸ |
| Example 28 | Au | HfN | 5.5 | >10⁸ |
| Example 29 | Au | VN | 6.1 | >10⁸ |
| Comparative | Au | NbN | 15.5 | >10⁸ |
| Example 19 | | | | |
| Comparative | Au | TaN | 21.3 | >10⁸ |
| Example 20 | | | | |

As is apparent from Table 9, in the Examples 26 to 29, it was confirmed that the initial contact resistances are very low, that is, 2.0 to 6.1Ω and all of the lifetimes are very long, that is, 10⁸ times or more in MEMS switches in which Au is used as the fixed electrode 3 and TiN, ZrN, HfN and VN are used as the lower electrode 5. The reason is as follows. It can be supposed that the advantages are obtained because Au is deformed to maintain a large contact area, resulting in a reduction in a contact resistance in an initial contact, and furthermore, the metal nitrides are not fusion bonded to Au.

On the other hand, in the Comparative Examples 19 and 20, there was confirmed a result that all of the lifetimes are very long, that is, 10⁸ times or more but the initial contact resistance is very high, that is, 15Ω or more in MEMS switches using Au as the fixed electrode 3 and using NdN and TaN as the lower electrode 5. The reason is as follows. It can be supposed that NbN and TaN have large specific resistance values.

### OTHER EXAMPLES AND COMPARATIVE EXAMPLES

Also in an investigation in which TiN, ZrN, HfN and VN which are excellent in the Examples 26 to 29 are used and a mixing ratio of an alloy of two selected metals, an alloy of three selected metals, and each of the four metals to Au is assigned, the same results can be obtained.

While the description has been given to the embodiment in which Au is used for the fixed electrode and the other metals and metal nitrides are used for the lower electrode in the examples and the comparative examples, the invention is not limited thereto but it is apparent that the same advantages can be obtained even if Au is used for the lower electrode and the other metals and metal nitrides are used for the fixed electrode.

What is claimed is:

1. A Micro-Electro-Mechanical System (MEMS) switch comprising:
a substrate;
a fixed electrode provided on the substrate; and
a beam fixed to the substrate and including a movable electrode disposed to face the fixed electrode, and the beam capable of being bent and displaced in a direction of the substrate to allow the movable electrode to directly contact with the fixed electrode,
wherein at least one of the fixed electrode and the movable electrode contains Au, and the other contains at least one metal selected from a group consisting of Ir, Rh, Os, Ru, Re and Te as a main component.

2. The switch according to claim 1, wherein the other contains an alloy of Au and one selected from the group.

3. The switch according to claim 2, wherein the weight percentage of the one metal in the alloy is equal to or larger than 50%.

4. The switch according to claim 1,
wherein the substrate has a trench on which the fixed electrode is disposed, and
wherein the beam is fixed to the substrate except an area where the trench is provided.

5. The switch according to claim 4, wherein the beam further includes: an upper electrode; and a piezoelectric layer sandwiched between the movable electrode and the upper electrode.

6. The switch according to claim 1, further comprising a fixing member disposed on the substrate and below the beam to fix the beam to the substrate.

7. The switch according to claim 6, wherein the beam further includes: an upper electrode; and a piezoelectric layer sandwiched between the movable electrode and the upper electrode.

8. A Micro-Electro-Mechanical System (MEMS) switch comprising:
a substrate;
a fixed electrode provided on the substrate; and
a beam fixed to the substrate and including a movable electrode disposed to face the fixed electrode, and the beam capable of being bent and displaced in a direction of the substrate to allow the movable electrode to directly contact with the fixed electrode,
wherein at least one of the fixed electrode and the movable electrode contains Au, and the other contains at least one metal selected from a group consisting of TiN, ZrN, HfN and VN as a main component.

9. The switch according to claim 8, wherein the other contains an alloy of Au and one metal selected from the group.

10. The switch according to claim 9, wherein the weight percentage of the one metal in the alloy is equal to or larger than 50%.

11. The switch according to claim 8,
wherein the substrate has a trench on which the fixed electrode is disposed, and
wherein the beam is fixed to the substrate except an area where the trench is provided.

12. The switch according to claim 11, wherein the beam further includes: an upper electrode; and a piezoelectric layer sandwiched between the movable electrode and the upper electrode.

13. The switch according to claim 8, further comprising a fixing member disposed on the substrate and below the beam to fix the beam to the substrate.

14. The switch according to claim 13, wherein the beam further includes: an upper electrode; and a piezoelectric layer sandwiched between the movable electrode and the upper electrode.
